(19) United States
(12) Patent Application Publication
(10) Pub. No.: US 2022/0097199 A1
(43) Pub. Date: Mar. 31, 2022

(54) METHOD AND DEVICE OF CHEMICAL MECHANICAL POLISHING

(71) Applicant: Zing Semiconductor Corporation, Shanghai (CN)

(72) Inventors: Youhe SHA, Shanghai (CN); Yue XIE, Shanghai (CN)

(73) Assignee: Zing Semiconductor Corporation, Shanghai (CN)

(21) Appl. No.: 17/154,850

(22) Filed: Jan. 21, 2021

(30) Foreign Application Priority Data
Sep. 28, 2020 (CN) 202011042568.1

(51) Int. Cl. B24B 37/04; H01L 21/461

(52) U.S. Cl. CPC B24B 37/04; H01L 21/461

(57) ABSTRACT

The present application provides a method and a device of chemical mechanical polishing (CMP). The method comprises providing a semiconductor wafer to be subjected to polishing; conducting a CMP process to the wafer, wherein the wafer is on a first plane; conducting a hanging treatment, wherein, in the hanging treatment, the wafer is on a second plane above the first plane, the wafer is hanged to expose the lower surface, and the wafer is in rotation. According to the present application, the hanging treatment can remove the slurry, the polishing particles and byproducts from the wafer surface, therefore, it prevents from the adverse effects caused by the polishing particles and byproducts on the wafer in the following process.

### BACKGROUND OF THE INVENTION

### 1. Field of the Invention

The present application relates to the technical field of semiconductor, in particular to a method and a device of chemical mechanical polishing.

### 2. Description of the Related Art

In the semiconductor manufacture process, from wafer production to device formation, chemical mechanical polishing (CMP) process may be conducted for the semiconductor wafer for several times. Since the applied CMP slurry carries a lot of particles and the byproducts as well as the debris are produced during the CMP process, these materials are attached to the surface of the semiconductor wafer. As shown in FIG. 1, the polishing head 101 carries the semiconductor wafer 100 to conduct CMP process on a surface of a polishing pad 102. A slurry 103 is provided to the surface of the polishing pad 102. The slurry 103 contains polishing particles P1. The wafer 100 reacts with the slurry 103 to form byproduct particles P2. These particles P1 and P2 usually attach to the surface of the wafer 100 and adversely affect the following process.

For example, while the CMP process has to be conducted for several times, a stock polishing is conducted to the wafer and followed by a fine polishing to achieve a desired polishing effects on the wafer. The polishing particles and the byproduct particles in the stock polishing process adversely affect the following fine polishing process. For another example, a washing process is conducted after the CMP process, but the washing effect is adversely affected by the polishing particles and the byproduct particles attached to the wafer surface.

To solve the conventional problems, the present application provides a CMP process.

### SUMMARY

In the summary of the invention, a series of concepts in a simplified form is introduced, which will be described in further detail in the detailed description. This summary of the present invention does not intend to limit the key elements or the essential technical features of the claimed technical solutions, nor intend to limit the scope of the claimed technical solution.

To solve the problem in the conventional technology, the present application provides a method of chemical mechanical polishing (CMP) comprising: providing a semiconductor wafer to be subjected to polishing; conducting a CMP process to the wafer, wherein the wafer is on a first plane during the CMP process; conducting a hanging treatment, wherein, in the hanging treatment, the wafer is on a second plane above the first plane, the wafer is hanged to expose the lower surface, and the wafer is in rotation.

### BRIEF DESCRIPTION OF THE DRAWINGS

FIG. 1 shows a schematic view of particles and byproducts attached on a wafer surface subjected to a CMP process.

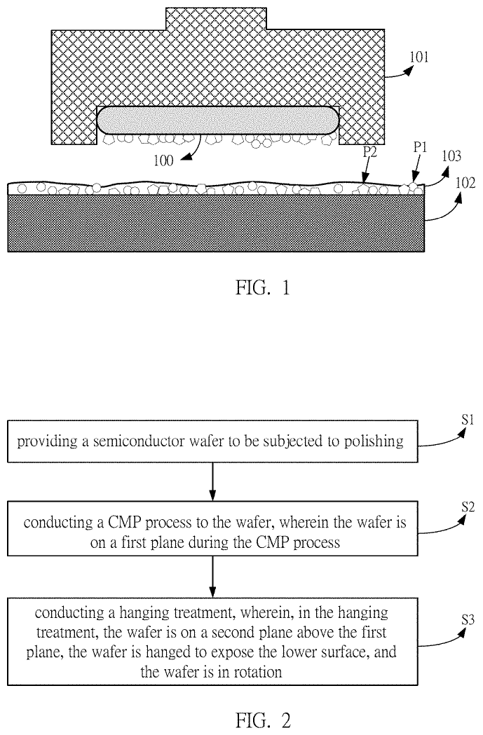

FIG. 2 shows a flow chart of a CMP process in accordance with an embodiment of the present application.

FIGS. 3A-3C show a schematic view of a position of the polishing head carrying the wafer in a CMP process in accordance with an embodiment of the present application.

### DETAILED DESCRIPTION OF THE EMBODIMENTS

The present application provides a method of chemical mechanical polishing (CMP) comprising: providing a semiconductor wafer to be subjected to polishing; conducting a CMP process to the wafer, wherein the wafer is on a first plane during the CMP process; conducting a hanging treatment, wherein, in the hanging treatment, the wafer is on a second plane above the first plane, the wafer is hanged to expose the lower surface, and the wafer is in rotation.

In one embodiment, in the CMP process, the wafer is at a first position of the first plane during the CMP process, and at a second position above the first position during the hanging treatment.

In one embodiment, the CMP process comprises a first CMP process and a second CMP process, and the hanging treatment comprises a first hanging treatment conducted after the first CMP process and before the second CMP process.

In one embodiment, the first CMP process is stock polishing, and the second CMP process is fine polishing.

In one embodiment, the hanging treatment further comprises a second hanging treatment conducted after the second CMP process.

In one embodiment, the method further comprises a washing step for the semiconductor wafer. The second hanging treatment is conducted after the second CMP process and before the washing step, and, in the second hanging treatment, the wafer is at a third position located in a wafer unloading area.

In one embodiment, the third position is in a wafer unloading area.

In one embodiment, the wafer has a rotation speed of 100-200 rpm in the hanging treatment.

The present application also provides a CMP device, the CMP device comprises a polishing head for carrying a semiconductor wafer and driving a motion of the wafer. The motion comprises a first motion and a second motion. During the first motion, the CMP process is conducted, wherein the polishing head is on a first plane during the CMP process. During the second motion, a hanging treatment is conducted, wherein, in the hanging treatment, the wafer is on a second plane above the first plane, the wafer carried by the polishing head is hanged to expose the lower surface, and the polishing head rotates.

In one embodiment, the device further comprises a washing liquid supply device for supplying the washing liquid to a surface of a polish pad during the hanging treatment.

In one embodiment, a position that the polishing head is located during the hanging treatment comprises a first position, and the first position is above the position of the polishing head during the CMP process.

In one embodiment, the device further comprises: a wafer unloading device for unload the wafer from the polishing head, wherein a position that the polishing head is located during the hanging treatment comprises a third position, and the third position is above the wafer unloading device.

According to the CMP method and the CMP system of the present application, after the CMP process, the wafer is lifted to a certain height and away from the polish pad, then the wafer is subjected to the hanging treatment, i.e. the polishing head drives the wafer to rotate. The attached slurry, particles and byproducts in the CMP process can be removed from the wafer surface because of centrifugal force and gravity, therefore, it prevents from the adverse effects caused by the polishing particles and byproducts on the wafer in the following processes such as fine polishing or washing. Accordingly, particle defects of the entire polishing process can be reduced.

### EXAMPLES

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

For a thorough understanding of the present invention, the detailed steps will be set forth in detail in the following description in order to explain the technical solution of the present invention. The preferred embodiments of the present invention is described in detail as follows, however, in addition to the detailed description, the present invention also may have other embodiments.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

It should be understood that the present invention may be practiced in different forms and that neither should be construed to limit the scope of the disclosed examples. On the contrary, the examples are provided to achieve a full and complete disclosure and make those skilled in the art fully receive the scope of the present invention. In the drawings, for clarity purpose, the size and the relative size of layers and areas may be exaggerated. In the drawings, same reference number indicates same element.

### Example 1

To solve the problem in the conventional technology, the present application provides a CMP method. The CMP method comprises providing a semiconductor wafer to be subjected to polishing; conducting a CMP process to the wafer, wherein the wafer is on a first plane during the CMP process; conducting a hanging treatment, wherein, in the hanging treatment, the wafer is on a second plane above the first plane, the wafer is hanged to expose the lower surface, and the wafer is in rotation.

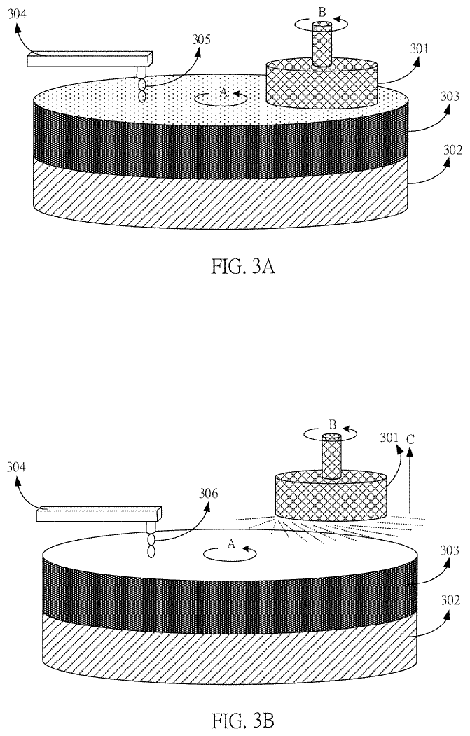

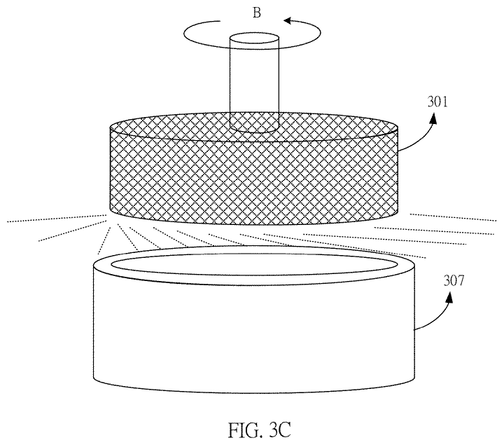

Referring FIG. 2 and FIGS. 3A-3C, the CMP method of the present application is described illustratively. FIG. 2 shows a flow chart of the CMP process in accordance with an embodiment of the present application. FIGS. 3A-3C show a schematic view of the relative positions of the polishing pad and the wafer in the CMP process in accordance with an embodiment of the present application.

Firstly, referring FIG. 2, conducting Step S1: providing a wafer to be subjected to polishing.

The wafer to be subjected to polishing can be any wafer which has to be polished by applying the CMP process in any semiconductor manufacture. The wafer includes, but not be limited to, any silicon wafer which has to be subjected to the CMP process in any semiconductor silicon wafer manufacture, any semiconductor wafer that has a semiconductor device formed thereon and has to be polished by applying the CMP process in any semiconductor device manufacture, and the like.

In this example, the wafer is a silicon wafer which has to be subjected to the CMP process in the semiconductor silicon wafer manufacture. A silicon ingot is pulled and formed, then is sliced to produce wafers. The sliced wafer has to be processed by the CMP method to have qualified surface roughness and granularity for the following semiconductor device manufacture.

Referring FIG. 2, conducting Step S2: conducting a CMP process to the wafer, wherein the wafer is on a first plane during the CMP process.

Referring FIG. 3A, it shows the relative positions of the polishing pad and the wafer on the first plane while the CMP process is conducted.

As shown in FIG. 3A, the CMP process is conducted by applying the CMP device of the present application. The CMP device comprises a polishing head 301 for carrying a wafer (not shown), a polishing platform 302 for bearing a polishing pad 303; and a liquid supply device 304 for supplying a polishing slurry 305 onto the polishing pad 303. The CMP device further comprises a driving device (not shown) for driving the motion of the polishing head.

As shown in FIG. 3A, in the step S2, the polishing head 301 carries a wafer on a first plane. The first plane is the plane that the surface of the polishing pad 303 locates. The polishing platform 302 carries the polishing pad 303 to rotate. In this example, as shown in FIG. 3A, the polishing platform 302 and the polishing pad 303 rotate counterclockwise along with the arrow A, and the polishing head 301 rotates counterclockwise along with the arrow B simultaneously. The wafer has a relative motion to the polishing pad 303, and the CMP process is conducted to the wafer accordingly.

In the CMP process, the polishing head drives the wafer to rotate to be subjected to the chemical mechanical polishing. In the following steps, it can lift the polishing head without change of the rotation state including rotation speed, direction and the like to conduct the hanging treatment. Thereby, the desired effect of the present application is achieved by the easy operation. In addition, by applying the lift of the polishing head to conduct the hanging treatment, the slurry, the contained particles and the byproducts can be left on the polishing pad and do not enter the next wafer processing step, so that the adverse effects caused by the particles and byproducts can be eliminated.

It should be noted that, as shown in FIG. 3A, the CMP process is conducted by applying the counterclockwise rotation of the polishing head and the polishing platform is merely exemplified. A person having ordinary skills in the art understands that any mean to produce relative motion between the wafer and the pad can achieve the CMP effects. It merely illustratively describes in this example that the wafer rotates counterclockwise about its axis during the CMP process. The other rotation means including rotation about the platform axis or random axis can be applied in the present application.

It should be noted that, for the CMP process of the present application, the CMP device of this example is illustratively exemplified but not to be the limitation, and a person having ordinary skills in the art is able to select the suitable CMP device if needed.

Referring FIG. 2, it conducts the step S3: conducting a hanging treatment, wherein, in the hanging treatment, the wafer is on a second plane above the first plane, the wafer is hanged to expose the lower surface, and the wafer is in rotation.

After the CMP process, the wafer is moved to the second plane, wherein the second plane is above the first plane. The wafer is hanged to expose its lower surface. During the hanging treatment, the wafer keeps its rotation. Because of the wafer rotation, the slurry, particles and byproducts adhered on the wafer surface in the CMP process can be removed from the wafer surface because of centrifugal force and gravity. Thereby, the adverse effects to the following processing steps such as fine polishing step or washing step caused by the particles and byproducts can be prevented.

It should be noted that, in the present application, the first plane and the second plane are two different levels with different heights. It merely limits the height of the wafer's position on the first and the second planes, but does not limit the wafer's locations within the two planes. Namely, the desired effects of the present application can be achieved by moving the wafer from the first location in the CMP process to a second location which is different from the first location to expose the lower surface of the wafer.

In one embodiment, the wafer is at a first position of the first plane during the CMP process, and at a second position above the first position during the hanging treatment

Referring FIG. 3A and FIG. 3B, according to the CMP method of the present application, after the step of the CMP process as shown in FIG. 3A, the polishing head 301 is directly lifted with a certain height to hang the polishing head 301 to expose the lower surface, i.e. to expose the lower surface of the wafer. While the polishing head 301 carries the wafer to rotate with the direction as indicated by the arrow B in the CMP process as shown in FIG. 3A, the polishing head 301 carrying the wafer locates at the first position. In the step S3, it merely lifts the polishing head 301 after completion of the CMP process. As shown in FIG. 3B, after completion of the step S2, the polishing head 301 carrying the wafer is lifted with the direction as indicated by the arrow C to the second plane. At this time, the polishing head 301 carrying the wafer is at the second position. The second position is higher than the first position. Simultaneously, the polishing head 301 keeps rotating with the direction indicated by the arrow B, so that the wafer is subjected to the hanging treatment under the rotation with the arrow B. As indicated by the dotted line in FIG. 3B, the slurry, particles and byproducts adhered on the wafer surface in the CMP process can be removed from the wafer surface because of centrifugal force and gravity. Thereby, the adverse effects to the following processing steps caused by the particles and byproducts can be prevented.

In one embodiment, in the CMP process, the wafer rotates at the first position on the first plane, and the rotation states of the wafer is identical in the CMP process and in the hanging treatment.

As shown in FIG. 3B, after completion of the step S2, the polishing head 301 carrying the wafer is lifted to the second position of the second plane. It merely change the position of the polishing head 301 but does not change the motion state of the polishing head 301. Thereby the hanging treatment is simplified because of the consistency of the motion states of wafer from the CMP process to the hanging treatment.

In one embodiment, the wafer has a rotation speed of 100-200 rmp in the hanging treatment. In one embodiment, the wafer has a rotation speed of 120 rmp in the hanging treatment, and 15% of the reduction of particle defect is achieved as comparing to the wafer without the hanging treatment.

In one embodiment, the hanging treatment further comprises a washing step for the polishing pad.

As shown in FIG. 3B, the polishing platform 302 carries the polishing pad 303 to rotate along with the arrow A, and the polishing head 301 carries the wafer to lift along with the arrow C to the second plane. At the same time, the polishing head 301 keeps to rotate along with the arrow B and enters the hanging treatment, and the liquid supply device 304 provides a washing liquid 306 for washing the pad 305. By applying the washing step to the polishing pad in the hanging treatment, it prevents from adverse effects caused by the slurry, particles and byproducts removed from the hanged wafer to the wafer left on the pad to be subjected to the CMP process.

In one embodiment, the washing liquid 306 can be a basic washing liquid such as SC1 and/or deionized water.

In one embodiment, the hanging treatment further comprises washing the wafer. The unloading plate includes a spiracle (not shown). When opening the spiracle, deionized water is sprayed to the wafer surface to washing the wafer in the hanging treatment.

While rotating and washing the wafer simultaneously, it ensures to remove the slurry, particles and byproducts adhered on the wafer surface in the CMP process from the wafer surface by the water in addition to the actions of centrifugal force and gravity.

In one embodiment, the CMP process comprises a first CMP process and a second CMP process, and the hanging treatment comprises a first hanging treatment conducted after the first CMP process and before the second CMP process.

In the manufactures of silicon wafer and semiconductor, the CMP process has to be conducted for several times to achieve a desired polishing effects on the wafer. In one embodiment of the manufactures of silicon wafer, the two-step polishing is applied, i.e. a stock polishing is conducted to the wafer and followed by a fine polishing. Stock polishing pad and stock polishing slurry are applied to the stock polishing, while fine polishing pad and fine polishing slurry are applied to the fine polishing. Byproducts of the stock polishing is different from that of the fine polishing. To avoid the effects of the polishing particles and the byproduct particles in the stock polishing process to the following fine polishing process, the hanging treatment is conducted to the wafer after the stock polishing process. The above adverse effects can be significantly reduced by the hanging treatment.

In one embodiment, the first position is the position of the wafer during the CMP process, and the second position is the position of the wafer during the hanging treatment.

By conducting the hanging treatment after the first CMP process, the wafer is at the position above the position of the first CMP process, and the first CMP slurry, the particles of the first CMP slurry, and the first byproduct are removed from the wafer to left on the first CMP pad. Thereby, their adverse effects to the second CMP pad as well as the second CMP process can be prevented. Further, the hanging treatment can comprise a washing step of the pad to washing and removing the first CMP slurry, the particles of the first CMP slurry, and the first byproduct from the first CMP pad.

As such, the hanging treatment is added between the first CMP process and the second CMP process. A person having ordinary skills in the art can reasonably dispose the time of the hanging treatment based on the real process.

In one embodiment, the hanging treatment further comprises a second hanging treatment after the second CMP process.

By applying the second hanging treatment after the second CMP process, it prevents from adverse effects to the following process caused by the second slurry, the particles in the second slurry and the second byproducts of the second CMP process.

In one embodiment, the method further comprises a washing step of the wafer. The hanging treatment comprises the second hanging treatment after the CMP process and before the washing step. In the second hanging treatment, the wafer locates in the wafer unloading area.

In embodiments of the above stock polishing and fine polishing, the fine polishing is the second CMP process. However, residual polishing slurry and particles and the byproducts are left after the fine polishing. To avoid the effects caused by the slurry, particles and byproducts to the following washing step, the second hanging treatment is conducted after the second CMP process. The second hanging treatment is prior to the washing step, and the position of the second hanging treatment is in the wafer unloading area, as shown in FIG. 3C. After the CMP process, the wafer is unloaded from the polishing head 301 to the wafer unloading device 307. The unloading device 307 transfers the wafer to the washing position, which is distinct from the position of the first hanging treatment, i.e. the position above the first position of the first polishing process. The position of the second hanging treatment is not above the pad of the CMP process and does not affect the following polishing process. Accordingly, the time cost of the product line of the CMP process will not increase. A person having ordinary skills in the art can reasonably dispose the time of the hanging treatment based on the real process.

### Example 2

The present application provides a device of chemical mechanical polishing. The device comprises a polishing head for carrying a semiconductor wafer and driving a motion of the wafer. The motion comprises a first motion and a second motion. The CMP process is conducted during the first motion, and the polishing head is on a first plane during the CMP process. The hanging treatment is conducted during the second motion, and, in the hanging treatment, the wafer is on a second plane above the first plane. The wafer carried by the polishing head is hanged to expose the lower surface. During the hanging treatment, the polishing head rotates.

Referring to FIG. 3A-FIG. 3C, the device is illustratively described.

Referring to FIG. 3A, the CMP device comprises the polishing head 301 for carrying a semiconductor wafer (not shown), the polishing platform 302 for bearing the polishing pad 303, and the liquid supply device 304 for providing the polishing slurry 305 onto the polishing pad 303. The CMP device further comprises a driving device (not shown) for driving the motion of the polishing head.

As shown in FIG. 3A, during the first motion, the polishing head 301 carries the wafer and conducts the CMP process on the first plane. The first plane is the plane that the surface of the polishing pad 303 locates. The polishing platform 302 carries the polishing pad 303 to rotate. In this example, as shown in FIG. 3A, the polishing platform 302 and the polishing pad 303 rotate counterclockwise along with the arrow A, and the polishing head 301 rotates counterclockwise along with the arrow B simultaneously. The wafer has a relative motion to the polishing pad 303, and the CMP process is conducted to the wafer accordingly.

After the CMP process as shown in FIG. 3A, referring FIG. 3B, during the second motion, the polishing head 301 carries the wafer and conducts the hanging treatment on the second plane. In the hanging treatment, the polishing head 301 locates on the second plane, in which the second plane is above the first plane, and the wafer carried by the polishing head 301 exposes its lower surface (not shown). The polishing head keeps rotation during the hanging treatment.

In the hanging treatment, as indicated by the dotted line in FIG. 3B, the slurry, particles and byproducts adhered on the wafer surface in the CMP process are removed from the wafer surface because of centrifugal force and gravity. Thereby, the adverse effects to the following processing steps caused by the slurry, particles and byproducts can be prevented.

In one embodiment, the CMP device further comprises a washing liquid supply device for supplying the washing liquid onto the surface of the polish pad during the hanging treatment.

While the polishing head 301 keeps the rotation along with the arrow B and conducts the hanging treatment, the liquid supply device 304 as an example of the washing liquid supply device in this embodiment supplies the washing liquid 306 to wash the polish pad 305. To prevent from the adverse effects to a semiconductor wafer on the pad to be subjected to the following CMP process caused by the removed slurry, particles and byproducts of the hanging treatment, the washing step of the pad and the hanging treatment are conducted simultaneously.

In one embodiment, the washing liquid 306 can be a basic washing liquid such as SC1 and/or deionized water.

In one embodiment of the CMP device, the position of the polishing head in the hanging treatment comprises a second position. The second position is above the position that the polishing head locates in the CMP process.

As shown in FIG. 3A-FIG. 3B, while the wafer enters the second motion from the first motion, the polishing head 301 is directly lifted with a certain height to hang the polishing head 301 to expose the lower surface, i.e. to expose the lower surface of the wafer. While the polishing head 301 carries the wafer to rotate with the direction as indicated by the arrow B in the CMP process as shown in FIG. 3A, the polishing head 301 carrying the wafer locates at the first position. In the step S3, it merely lifts the polishing head 301 after completion of the CMP process. As shown in FIG. 3B, after completion of the step S2, the polishing head 301 carrying the wafer is lifted with the direction as indicated by the arrow C to the second plane. At this time, the polishing head 301 carrying the wafer is at the second position. The second position is higher than the first position. Simultaneously, the polishing head 301 keeps rotating with the direction indicated by the arrow B.

In one embodiment, in the CMP process, the wafer rotates at the first position on the first plane, and the rotation states of the wafer is identical in the CMP process and in the hanging treatment.

As shown in FIG. 3B, after completion of the step S2, the polishing head 301 carrying the wafer is lifted to the second position of the second plane as indicated by the arrow C. It merely change the position of the polishing head 301 but does not change the motion state of the polishing head 301. Thereby the hanging treatment is simplified because of the consistency of the motion states of wafer from the CMP process to the hanging treatment.

According to the hanging treatment, the slurry, particles and byproducts attached on the wafer surface in the CMP process can be left in the CMP processing area. Additional processing area of the hanging treatment is not necessary. The system arrangement can be simplified accordingly.

In one embodiment, the CMP device further comprises a wafer unloading device for unload the wafer from the polishing head. The position that the polishing head locates during the hanging treatment comprises a third position, and the third position is above the unloading device.

As shown in FIG. 3C, after the CMP process, the wafer is unloaded from the polishing head 301 to the unloading device 307. The unloading device 307 transfers the wafer to the washing position, which is distinct from the position of the first hanging treatment, i.e. the position above the first position of the first polishing process. The position of the second hanging treatment is not above the pad of the CMP process and does not affect the following polishing process. Accordingly, the time cost of the product line of the CMP process will not increase. A person having ordinary skills in the art can reasonably dispose the time of the hanging treatment based on the real process.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure. The scope of the present invention is defined by the appended claims and their equivalent scope.

What is claimed is:

1. A method of chemical mechanical polishing (CMP) comprising:
providing a semiconductor wafer to be subjected to polishing;
conducting a CMP process to the wafer, wherein the wafer is on a first plane during the CMP process;
conducting a hanging treatment, wherein, in the hanging treatment, the wafer is on a second plane above the first plane, the wafer is hanged to expose the lower surface, and the wafer is in rotation.

2. The method of claim 1, wherein the wafer is at a first position of the first plane during the CMP process, and at a second position above the first position during the hanging treatment.

3. The method of claim 2, wherein the CMP process comprises a first CMP process and a second CMP process, and the hanging treatment comprises a first hanging treatment conducted after the first CMP process and before the second CMP process.

4. The method of claim 3, wherein the first CMP process is stock polishing, and the second CMP process is fine polishing.

5. The method of claim 3, wherein the hanging treatment further comprises a second hanging treatment conducted after the second CMP process.

6. The method of claim 1, further comprising a washing step for the semiconductor wafer, wherein the second hanging treatment is conducted after the second CMP process and before the washing step, and, in the second hanging treatment, the wafer is at a third position.

7. The method of claim 6, wherein the third position is in a wafer unloading area.

8. The method of claim 1, wherein the wafer has a rotation speed of 100-200 rpm in the hanging treatment.

9. A device of chemical mechanical polishing comprising:
a polishing head for carrying a semiconductor wafer and driving a motion of the wafer, wherein the motion comprises a first motion and a second motion;
during the first motion, the CMP process is conducted, wherein the polishing head is on a first plane during the CMP process;
during the second motion, a hanging treatment is conducted, wherein, in the hanging treatment, the wafer is on a second plane above the first plane, the wafer carried by the polishing head is hanged to expose the lower surface, and the polishing head rotates.

10. The device of claim 9, further comprising: a washing liquid supply device for supplying the washing liquid to a surface of a polish pad during the hanging treatment.

11. The device of claim 9, wherein a position that the polishing head is located during the hanging treatment comprises a first position, and the first position is above the position of the polishing head during the CMP process.

12. The device of claim 9, further comprising: a wafer unloading device for unload the wafer from the polishing head, wherein a position that the polishing head is located during the hanging treatment comprises a second position, and the second position is above the wafer unloading device.
